(19) United States
(12) Patent Application Publication
(10) Pub. No.: US 2012/0291847 A1
(43) Pub. Date: Nov. 22, 2012

(54) MULTI-PANEL SOLAR PANEL DEPLOYMENT DEVICE

(76) Inventors: David F. Rowe, JR., Clemmons, NC (US); John Gunn, Charlotte, NC (US); James D. MacNulty, Mocksville, NC (US)

(21) Appl. No.: 13/112,074

(22) Filed: May 20, 2011

(51) Int. Cl. H01L 31/045; H01M 10/46; B62D 47/00

(52) U.S. Cl. 136/245; 280/656; 320/101

(57) ABSTRACT

A mobile power unit includes a mobile trailer and a plurality of support posts coupled to the mobile trailer, each support post having an axis. The mobile power unit further includes a plurality of solar panels, at least one of the plurality of solar panels being pivotally coupled to one of the plurality of support posts such that the at least one of the plurality of solar panels can be rotated about the axis of the support post to which it is attached.

### BACKGROUND

The present invention relates to a multi-panel solar deployment device. More specifically, the invention relates to a mobile power unit which includes solar panels.

Mobile power units are used at many locations where electrical power provided by the power grid is not available. Traditionally, mobile power units have used internal combustion engine driven generators to generate power. However, in some applications, the engine may produce too much noise or may be difficult to fuel.

### SUMMARY

In one embodiment, the invention provides a mobile power unit which includes a mobile trailer, and a plurality of support posts coupled to the mobile trailer, each support post having an axis. The mobile power unit also includes a plurality of solar panels, at least one of the plurality of solar panels being pivotally coupled to one of the plurality of support posts such that the at least one of the plurality of solar panels can be rotated about the axis of the support post to which it is attached.

In another embodiment the invention provides a mobile power unit which includes a mobile trailer, and a plurality of solar panels, at least two of the plurality of solar panels capable of being folded into a stored position. The mobile power unit also includes a storage box coupled to the mobile trailer, the storage box receiving the at least two of the plurality of solar panels when the at least two of the plurality of solar panels are in the stored position, and a plurality of slides. Each slide is coupled to the storage box and one of the plurality of solar panels, and operable to slide at least one of the plurality of solar panels from a stored position inside the storage box to a deployed position outside of the storage box.

In yet another embodiment the invention provides a mobile power unit which includes a mobile trailer, and a plurality of support posts coupled to the mobile trailer, each support post having an axis. The mobile power unit also has a plurality of solar panels, each solar panel being pivotally coupled to one of the plurality of support posts such that the plurality of solar panels can be rotated about the axis of the support post the solar panel is attached to. The mobile power unit further includes a solar panel non-pivotally coupled to the trailer, a generator disposed in the interior of the trailer, a battery disposed in the interior of the trailer, the battery being electrically connected to the generator and solar panels to receive a charge therefrom, a control unit operable to automatically engage the generator when the battery voltage drops below a predetermined level, and a plurality of display panels, each display panel being coupled to at least one of the plurality of solar panels.

Other aspects of the invention will become apparent by consideration of the detailed description and accompanying drawings.

### BRIEF DESCRIPTION OF THE DRAWINGS

FIG. 1 is a side view of a mobile power unit in a stowed position.

FIG. 2 is a top view of the mobile power unit of FIG. 1, showing the solar panels in the stored position.

FIG. 3 is a top view of the mobile power unit of FIG. 1, in the deployed position.

FIG. 4 is a side view of the mobile power unit of FIG. 1, in the deployed position.

FIG. 5 is a perspective view of the mobile power unit of FIG. 1, in the deployed position.

FIG. 6 is a perspective view of a different embodiment of a mobile power unit.

FIG. 7 is a perspective view of the mobile power unit of FIG. 6, showing the solar panels in a partially deployed state.

FIG. 8 is a perspective view of the mobile power unit of FIG. 6, showing the solar panels in the deployed position.

FIG. 9 is a schematic illustration showing electrical components of the mobile power unit of FIG. 1.

FIG. 10 illustrates a swivel connection between an inner tube and a solar panel.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

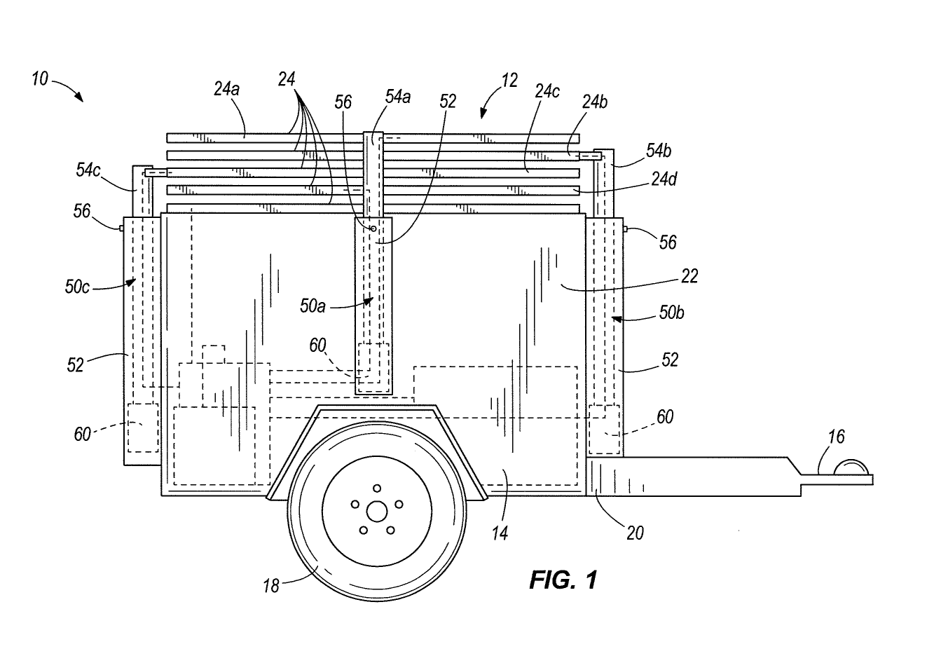

FIG. 1 illustrates a mobile power unit 10 that includes a multi-panel solar deployment device 12 supported by a trailer 14. The trailer 14 includes a tongue 16, wheels 18, a frame 20, and a housing 22. The illustrated construction includes two wheels 18 supported by the housing 22 for rotation. The tongue 16 provides a third support point for the trailer 14 and is arranged to facilitate attachment of the trailer 14 to a vehicle for towing. The frame 20 is fixedly attached to the trailer 14 or is formed as part of the trailer 14 and provides structural support for the housing 22 and any other components supported by the trailer 14. The housing 22 encloses a space that is sized to contain and protect several components as will be discussed below. In some constructions, the housing 22 includes apertures formed in the walls to allow for air flow into or out of the housing 22. In still other constructions, a fan or other air moving devices may be employed to enhance the cooling effect of the air moving through the housing 22.

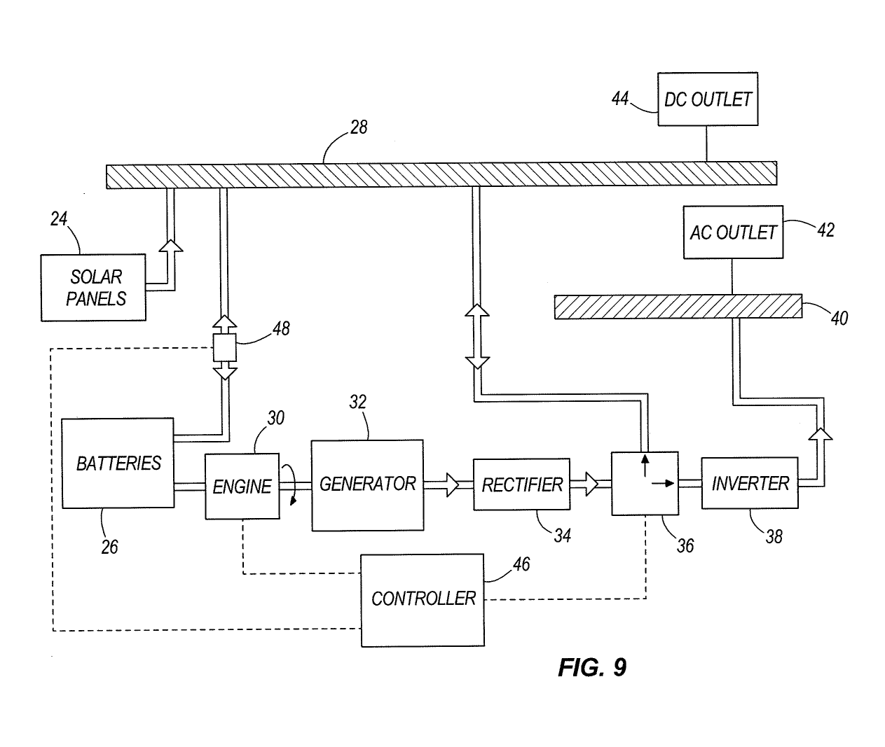

FIG. 9 schematically illustrates one arrangement of electrical components that may be disposed within the housing 22. Specifically, FIG. 9 illustrates an arrangement that includes solar panels 24 and batteries 26 that are operable to provide a DC current to a DC buss 28. An engine 30 and generator 32 are arranged to provide AC power to a rectifier 34 that in turn converts the AC signal to a DC signal. The DC signal is directed to a switch arrangement 36 that can be arranged to direct DC power to the DC buss 28 or alternatively to direct the DC power to an inverter 38. The inverter 38 converts the power to a desired frequency and voltage (e.g., 60 Hz, 120 volts) and then directs the AC power to an AC buss 40. The AC buss 40 is connected to an AC outlet 42 and the DC buss is connected to a DC outlet 44 to allow a user to connect AC and DC devices to the mobile power unit 10 as may be required.

A controller 46 is provided to control various aspects of the operation of the components of FIG. 9. For example, the controller 46 provides control signals to a switch assembly 48 between the batteries 26 and the DC buss 28 to control the direction of power flow between the batteries 26 and the DC buss 28. Thus, power can flow from the solar panels 24 to the DC buss 28 and from the DC buss 28 to the batteries 26 to charge the batteries 26. The controller 46 also controls the switch assembly 36 to control the flow of power from the rectifier 34 such that AC power or DC power is provided to the appropriate buss. In one construction, the switch assembly 36 can be arranged to provide power flow from the DC buss 28 to the inverter 38 and then to the AC buss 40. Thus, the solar panels 24 and/or batteries 26 can provide AC power if desired. In preferred constructions, all of the components illustrated in FIG. 9, with the exception of the solar panels 24 are located inside of the housing 22 to allow the housing 22 to provide them some level of protection. It should be noted that FIG. 9 illustrates one arrangement of the various components with many other arrangements being possible. Thus, the invention should not be limited by the arrangement of the components discussed with regard to FIG. 9.

With reference to FIG. 1, the mobile power unit 10 includes four support assemblies 50 and five solar panels 24. Each support assembly includes an outer tube 52 that is attached to the housing 22 and/or the frame 20. Each support assembly 50 also includes an inner tube 54 that includes a portion positioned within the outer tube 52 and an end connected to one of the solar panels 24. Each inner tube 54 is rotatable with respect to the outer tube 52 and is movable axially within the outer tube 52. In some constructions, a locking pin 56 is provided to lock the position of each inner tube 54 with respect to its outer tube 52. The pin 56 passes through apertures in the outer tube 52 and the inner tube 54 to lock the inner tube 54 in place. Of course other constructions could employ other locking arrangements.

Four of the five solar panels 24 are connected to one of the inner tubes 54 with the fifth solar panel 24 attached to a top portion of the housing 22. In one arrangement, each panel 24 is fixedly connected to its respective tube 54 so that the panel 24 cannot move with respect to the tube 54. In other constructions, a swivel connection 58 (illustrated in FIG. 10) is provided between each panel 24 and its respective inner tube 54 to allow the panel 24 to rotate about an axis that is normal to the long axis of the outer tube 52.

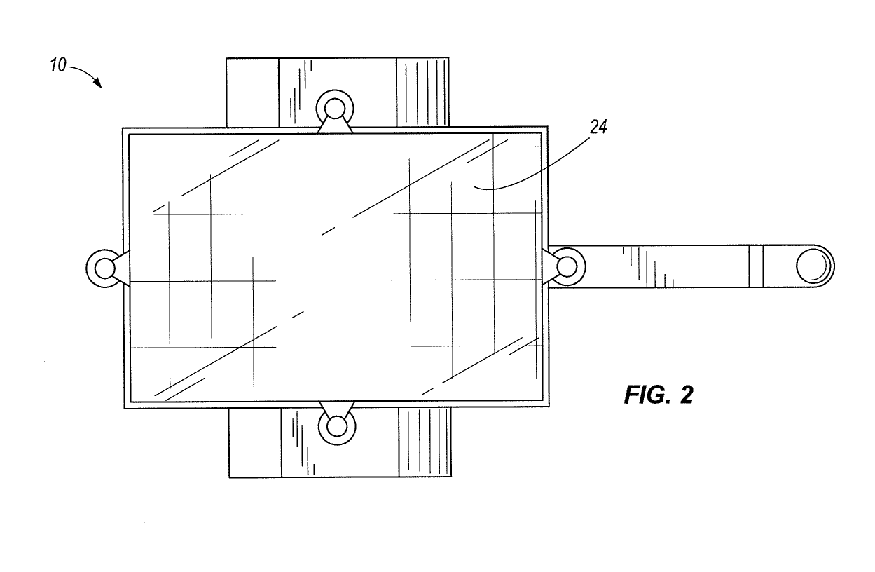

FIGS. 1 and 2 illustrate the solar panels 24 of the mobile power unit 10 in a stored position. In this position, the solar panels 24 align with one another to define a footprint that is about the same size as the footprint of the housing 22. It is preferable that the solar panels 24 not extend beyond the front, rear, or sides of the housing 24 in the stored position. As illustrated in FIG. 1, the fifth of the solar panels 24 is attached to the housing 22 with the remaining four solar panels 24 being arranged above the fifth solar panel 24.

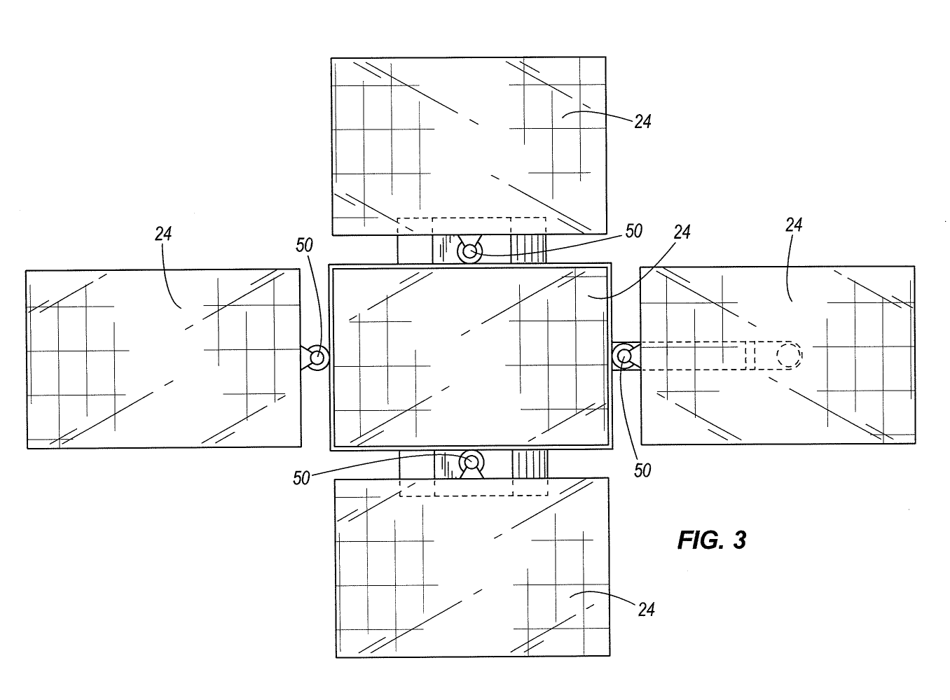

FIG. 3 illustrates the solar panels 24 in a deployed position. In this position, the solar panels 24 do not cover one another and are therefore exposed to additional sunlight. To move from the stored position of FIG. 1 to the deployed position of FIG. 3, the user rotates the top panel 24a 180 degrees about the long axis of the outer tube 52 of the support assembly 50a that supports the top panel 24a. The remaining three support assemblies 50 are preferably shorter than the height of the top panel 24a to allow free rotation of the top solar panel 24a without the need to lift the panel 24a and the inner tube 54a. However, if the arrangement is such that lifting the solar panel 24a is necessary, one could provide a hydraulic, electric, pneumatic, spring actuated, or other actuator 60 (illustrated in FIG. 1) that operates to lift the inner tube 54a and the solar panel 24a. The second solar panel 24b is next rotated 180 degrees to its deployed position. The second solar panel 24b is free to rotate in a direction away from the first support 50a as the remaining support assemblies 50 are lower than the second support assembly 50b. As with the first support assembly 50a, an actuator 60 could be positioned to lift the second solar panel 24b if desired. Next, the third solar panel 24c is rotated 180 degrees to its deployed position. The third solar panel 24c is free to rotate in a direction away from the second support 50b as the fourth support assembly 50d is lower than the third support assembly 50c. As with the first support assembly 50a and the second support assembly 50b, an actuator 60 could be positioned to lift the third solar panel 24c if desired. Finally, the fourth solar panel 24d is rotated 180 degrees to its deployed position. Unlike the first three solar panels 24, the fourth solar panel 24d must be lifted to clear the height of the first support assembly 50a and the third support assembly 50c. Thus, the fourth support assembly 50d includes the actuator 60 positioned to lift the inner tube 54d with respect to the outer tube 52 to allow free rotation of the solar panel 24d.

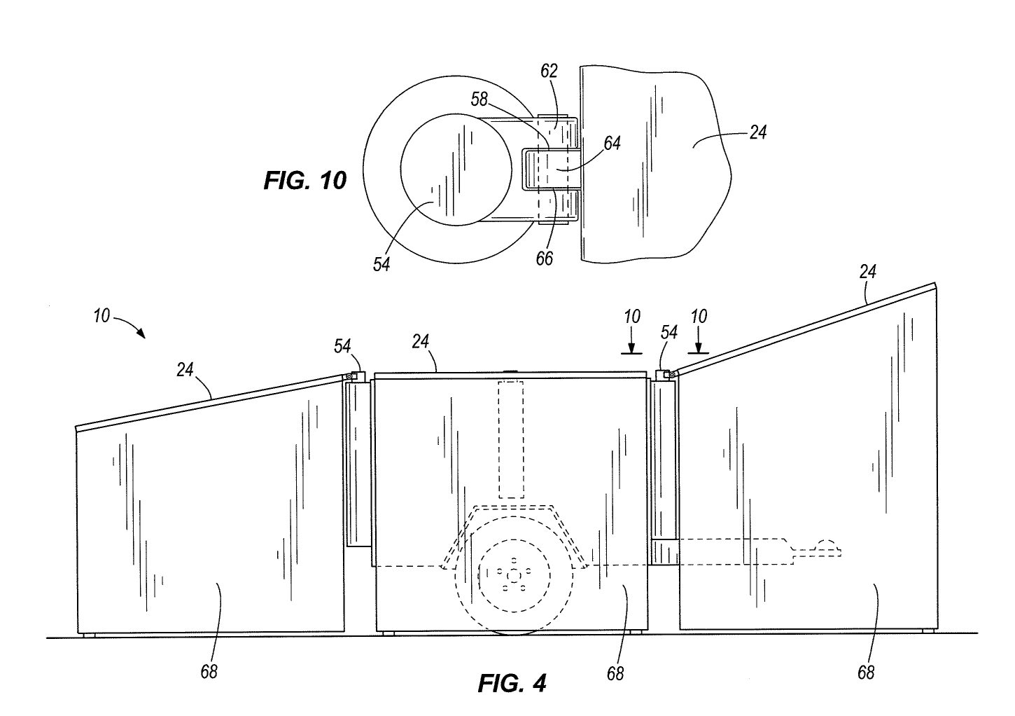

FIG. 4 illustrates a construction in which the solar panels 24 are rotatable with respect to their respective inner tubes 54 to provide for better alignment with the sun and to compensate for uneven ground. FIG. 10 illustrates one possible arrangement of a connection between the solar panel 24 and the inner tube 54 that provides one degree of rotation therebetween. As illustrated in FIG. 10, the connection 58 includes a yoke 62 attached to or formed as part of the inner tube 54 and a tab 64 attached to or formed as part of the solar panel 24. A pin 66 connects the tab 64 and yoke 62 and provides an axis of rotation. As one of ordinary skill will realize, another connection 58 similar to the one illustrated, but rotated 90 degrees could be employed to provide a second degree of freedom. In addition, other arrangements and rotatable joints could be employed if desired.

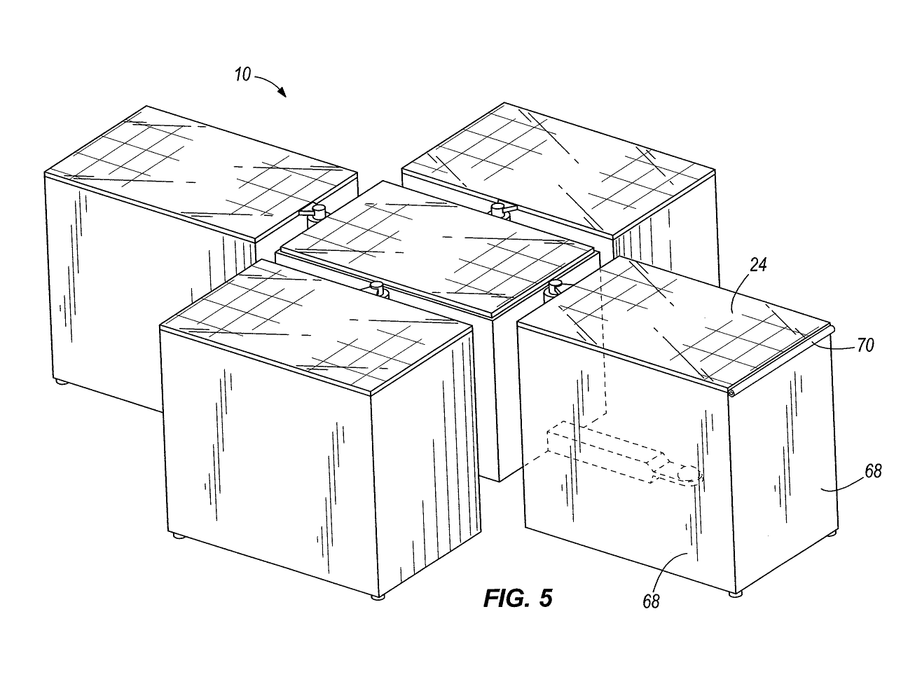

FIGS. 4 and 5 also illustrate several side panels 68 that are coupled to the solar panels 24 and are extendable to provide a skirt around the mobile power unit 10. In a preferred arrangement, the side panels 68 roll into a tube 70 that is attached to the side of the solar panel 24 for storage. A user then unrolls the side panels 68 from each of the tubes 70 after the panels 24 are arranged. In some constructions, the tubes 70 include a torsional biasing member that automatically rolls the side panels 68 into the tube shape when actuated. In some constructions, advertisements or other information is printed on the side panels 68.

In one construction, 216 watt solar panels 24 are used in the mobile power unit 10. With five panels 24, the mobile power unit 10 is capable of generating about 1,080 watts. Of course, other size or power configurations of the solar panels 24 are also possible. If more than 1,080 watts is required, the internal combustion engine 30 and generator 32 may be used. In one embodiment, the internal combustion engine 30 and generator 32 are capable of providing an additional 5,000 watts of power, with larger or smaller generator systems being possible.

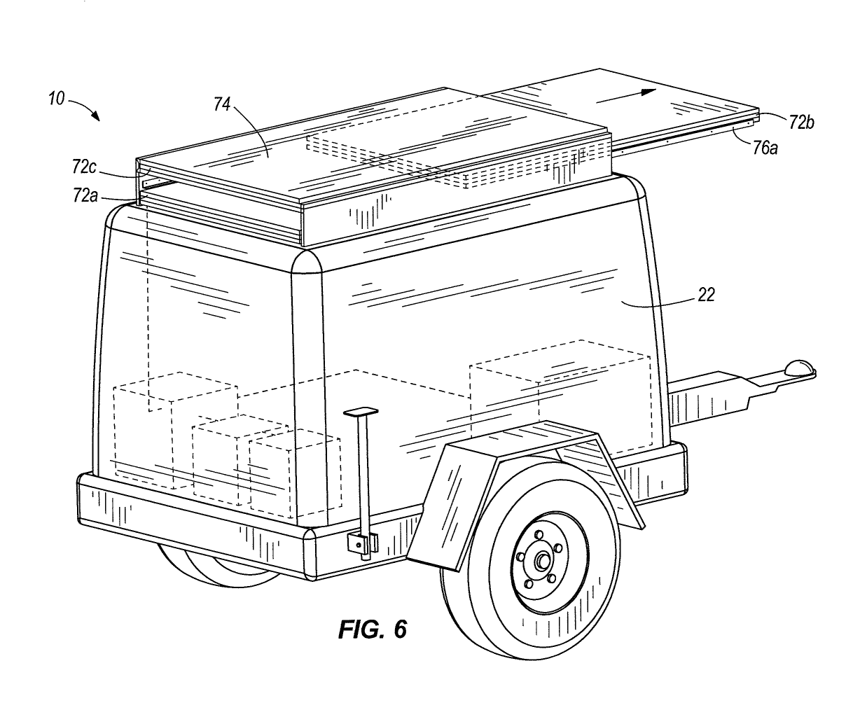

FIGS. 6-8 illustrate another construction of a mobile power unit 10 that is substantially the same as the mobile power unit 10 of FIGS. 1-5 with the exception of the arrangement of the solar panels 24. As illustrated in FIG. 6, the solar panels 24 are arranged in solar panel assemblies 72 that are stacked above the housing 22.

The first solar panel assembly 72a is disposed proximate the housing 22 and is supported within a housing 74 by a pair of drawer slides 76. The slides 76 attach to the first solar panel assembly 72a and the housing 74 and allow the first solar panel assembly 72a to slide linearly into and out of the housing 74. A second solar panel assembly 72b is disposed above the first solar assembly 72a and is supported in a similar manner as the first solar panel assembly 72a. The second solar panel assembly 72b is arranged to slide in the opposite direction as the first solar panel assembly 72a. A third solar panel assembly 72c is disposed above the second solar panel assembly 72b but does not slide in either direction.

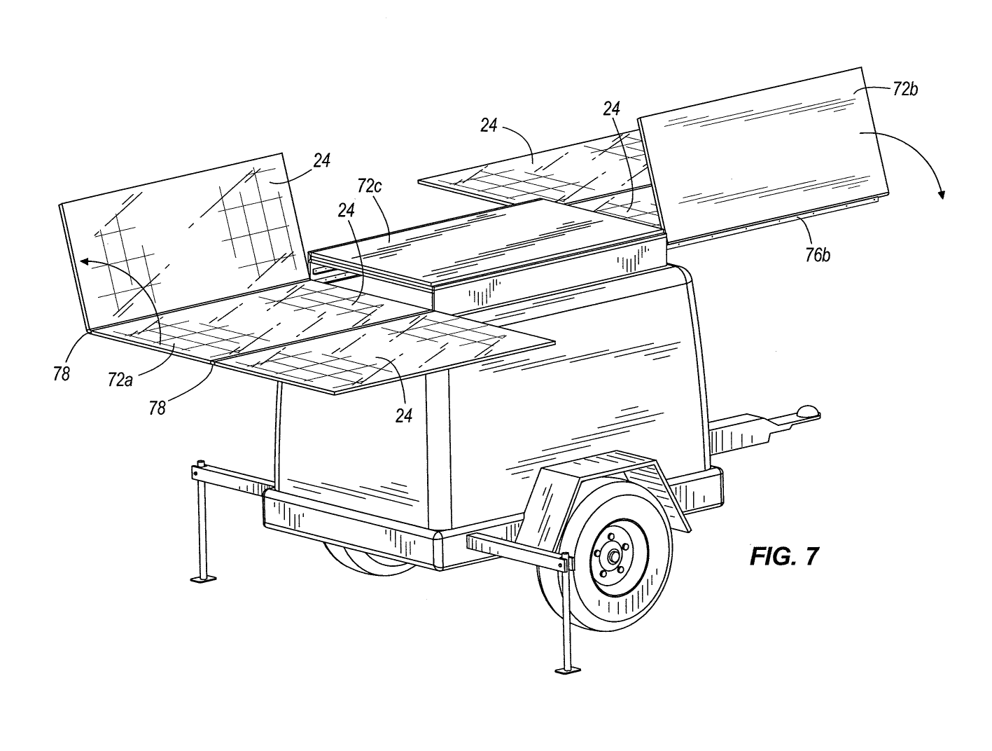

As illustrated in FIG. 7, once the first solar panel assembly 72a and the second solar panel assembly 72b are slid to their extended position, they along with the third solar panel assembly 72c can be unfolded. As illustrated, each solar panel assembly 72 includes the center panel 24 and two side panels 24 connected via hinge 78 to the center panel 24. Thus, once unfolded, the construction of FIG. 7 includes nine panels 24.

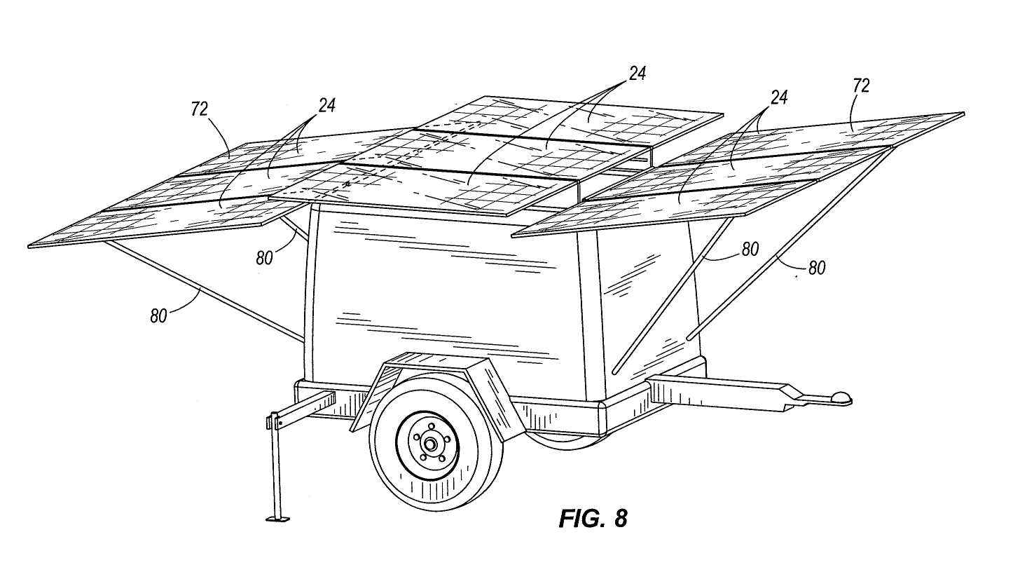

FIG. 8 illustrates the mobile power unit with the solar panels 24 in the extended position. The solar panel assemblies 72 that extend from the housing 74 include legs 80 that extend from the outer most end of the solar panel assemblies 72 toward the housing 22. The legs 80 provide additional support so that the slides 76 do not have to support the full weight of the solar panel assemblies 72. In preferred constructions, the length of each of the legs 80 is adjustable to allow the user to tip the solar panel assemblies 72 as desired. In some constructions, the legs 80 extend from the outer most end of the solar panel assemblies 72 to the ground.

Thus, the invention provides, among other things, a multi-panel solar deployment device. Various features and advantages of the invention are set forth in the following claims.

What is claimed is:

1. A mobile power unit comprising:
a mobile trailer;
a plurality of support posts coupled to the mobile trailer, each support post having an axis;
a plurality of solar panels, at least one of the plurality of solar panels being pivotally coupled to one of the plurality of support posts such that the at least one of the plurality of solar panels can be rotated about the axis of the support post to which it is attached.

2. The mobile power unit of claim 1, further comprising a solar panel that is coupled to the mobile trailer and is not rotatable.

3. The mobile power unit of claim 1, further comprising a battery connected to each of the solar panels to store an electrical charge produced by the solar panels.

4. The mobile power unit of claim 1, further comprising a plurality of display panels, each display panel being coupled to one of the plurality of solar panels.

5. The mobile power unit of claim 4, further comprising a plurality of screen housings, each screen housing being coupled to at least one of the plurality of display panels, each display panel being moved to a display position by pulling on the bottom of the display panel such that the display is unrolled.

6. The mobile power unit of claim 1, further comprising a generator coupled to the mobile trailer.

7. The mobile power unit of claim 6, further comprising a control unit and a battery, the battery being connected to each of the solar panels to store an electrical charge produced by the solar panels, the battery also being connected to the generator to store an electrical charge produced by the generator, and the control unit operable to automatically engage the generator when the battery voltage drops below a predetermined level.

8. The mobile power unit of claim 1, further comprising a hinge, the hinge being coupled to a support post and a solar panel such that a tilt angle of the solar panel is adjustable.

9. The mobile power unit of claim 1, further comprising a plurality of support legs, at least one of the plurality of support legs being coupled to an outer edge of at least one of the plurality of solar panels.

10. A mobile power unit comprising:
a mobile trailer;
a plurality of solar panels, at least two of the plurality of solar panels capable of being folded into a stored position;
a storage box coupled to the mobile trailer, the storage box receiving the at least two of the plurality of solar panels when the at least two of the plurality of solar panels are in the stored position; and
a plurality of slides, each slide being coupled to the storage box and one of the plurality of solar panels, and operable to slide at least one of the plurality of solar panels from a stored position inside the storage box to a deployed position outside of the storage box.

11. The mobile power unit of claim 10, further comprising a battery connected to store an electrical charge from at least one of the plurality of solar panels.

12. The mobile power unit of claim 10, further comprising a generator coupled to the mobile trailer.

13. The mobile power unit of claim 10, further comprising a plurality of support legs able to support the plurality of solar panels when the solar panels are in the deployed position.

14. The mobile power unit of claim 10, wherein at least two of the plurality of solar panels fold using hinges.

15. The mobile power unit of claim 10, further comprising a control unit, a generator and a battery, the battery being connected to each of the solar panels to store an electrical charge produced by the solar panels, the battery also being connected to the generator to store an electrical charge produced by the generator, and the control unit being configured to automatically engage the generator if the battery voltage drops below a predetermined level.

16. The mobile power unit of claim 10, further comprising a plurality of display panels, each display panel being coupled to one of the plurality of solar panels.

17. A mobile power unit comprising:
a mobile trailer;
a plurality of support posts coupled to the mobile trailer, each support post having an axis;
a plurality of solar panels, each solar panel being pivotally coupled to one of the plurality of support posts such that the plurality of solar panels can be rotated about the axis of the support post the solar panel is attached to;
a solar panel non-pivotally coupled to the trailer;
a generator disposed in the interior of the trailer;
a battery disposed in the interior of the trailer, the battery being electrically connected to the generator and solar panels to receive a charge therefrom;
a control unit operable to automatically engage the generator when the battery voltage drops below a predetermined level; and
a plurality of display panels, each display panel being coupled to at least one of the plurality of solar panels.

18. The mobile power unit of claim 17, further comprising a plurality of screen housings, each screen housing being coupled to at least one of the plurality of display panels, each display panel being moved to a display position by pulling on the bottom of the display panel such that the display is unrolled.

19. The mobile power unit of claim 17, wherein the control unit is operable to automatically engage the generator when the battery voltage drops below a predetermined level.

20. The mobile power unit of claim 17, further comprising a hinge, the hinge being coupled to a support post and a solar panel such that a tilt angle of the solar panel is adjustable.
